(19) United States
(12) Patent Application Publication
(10) Pub. No.: US 2007/0111433 A1
(43) Pub. Date: May 17, 2007

(54) Methods for manufacturing semiconductor devices

(76) Inventors: Shinichi Hirasawa, Tokyo (JP); Atsushi Shigeta, Fujisawa-shi (JP); Kiyotaka Miyano, Fujisawa-shi (JP); Yukiteru Matsui, Yokohama-shi (JP); Takeshi Nishioka, Yokohama-shi (JP); Hiroyuki Yano, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/594,726

(22) Filed: Nov. 9, 2006

(30) Foreign Application Priority Data
Nov. 11, 2005 (JP) P2005-327899

(51) Int. Cl. H01L 21/8242

(52) U.S. Cl. 438/253

(57) ABSTRACT

A method for manufacturing a semiconductor device comprises forming a first silicon layer above a semiconductor substrate; forming a stopper layer on said first silicon layer; partially removing said stopper layer and said first silicon layer above said semiconductor substrate to form a plurality of trenches; forming an insulating layer on said stopper layer with inside of said trenches; partially removing said insulating layer to expose said stopper layer; after partially removing said insulating layer, removing said stopper layer to expose said first silicon layer; selectively growing second silicon layer on said exposed first silicon layer; nonselectively growing a third silicon layer on said second silicon layer; and polishing at least a surface of said third silicon layer by performing chemical mechanical polishing.

### CROSS-REFERENCE TO RELATED APPLICATIONS

This application is based upon and claims the benefit of priority from the prior Japanese Patent Applications No. 2005-327899, filed on Nov. 11, 2005, the entire contents of which are incorporated herein by reference.

### TECHNICAL FIELD

The present invention relates to methods for manufacturing semiconductor devices, and in particular, relates to methods for manufacturing semiconductor devices using the damascene process.

### BACKGROUND OF THE INVENTION

Flash memories are broadly used as memory elements for multimedia cards since they can maintain memory without a power supply. In recent years, further large capacity of flash memory has been desired and thus further high integration of flash memory is necessary to realize such large capacity.

As one of methods for high integration of flash memory, a method which divides a silicon layer in the floating gates into first and second layers and forms two layers; performs element isolation after forming the first silicon layer; then in the step for forming the second silicon layer, only on the first silicon layer the second silicon layer is deposited in a self-alignment and selective manner, is proposed, as described in Japanese Patent Application Laid-open Disclosure No. 2001-118944 and U.S. Pat. No. 6,649,965.

These methods disclosed in Japanese Patent Application Laid-open Disclosure No. 2001-118944 and U.S. Pat. No. 6,649,965 comprise expanding and developing laterally the second silicon layer on the insulating layer for element isolation by selective growth, and forming floating gates. Using these methods may make the floating gates wider than the width of tunnel insulating layers, make the distance among the adjoining floating gates narrower than the minimum line width, and, as a result, may realize a high-capacity coupling ratio. Additionally, by using these methods, electric field concentration tends not to occur in the floating gates since the edge of the floating gates consequently have a rounded structure.

In this case, however, it is difficult to equalize the surface area of the silicon layer where the selective growth has occurred among each cell, and, as a result, there a variation in device characteristics based on the coupling ratio tends to occur. On the other hand, in U.S. Pat. No. 6,555,427 the damascene process, which leaves the second silicon layer on the first silicon layer by performing etch back or polishing after nonselective formation of the second silicon layer on the entire upper surface of the first silicon layer and the insulating layer for element isolation, is proposed. However, if the second silicon layer is formed nonselectively, it causes steps between the upper surface of the first silicon layer and the upper surface of the insulating layer for element isolation; and if further miniaturization of memory cell develops in the future, a forming failure of the second silicon layer may occur.

### BRIEF SUMMARY OF THE INVENTION

According to one aspect of the present invention, a method for manufacturing a semiconductor device comprising: forming a first silicon layer above a semiconductor substrate; forming a stopper layer on said first silicon layer; partially removing said stopper layer and said first silicon layer above said semiconductor substrate to form a plurality of trenches; forming an insulating layer on said stopper layer with inside of said trenches; partially removing said insulating layer to expose said stopper layer; after partially removing said insulating layer, removing said stopper layer to expose said first silicon layer; selectively growing second silicon layer on said exposed first silicon layer; nonselectively growing a third silicon layer on said second silicon layer; and polishing at least a surface of said third silicon layer by performing chemical mechanical polishing is provided.

According to another aspect of this invention, a method for manufacturing a semiconductor device comprising: forming a first insulating layer on a semiconductor substrate; forming a first silicon layer on said first insulating layer; forming a second insulating layer on said first silicon layer; partially removing said second insulating layer, said first silicon layer, said first insulating layer and said semiconductor substrate to form a plurality of trenches for isolation; filling said trenches for isolation with third insulating layers; after filling said trenches with third insulating layers, removing said second insulating layer to expose said first silicon layer; selectively growing a second silicon layer on said exposed first silicon layer; nonselectively growing a third silicon layer on said second silicon layer and said third insulating layers; planarizing said third silicon layer and said second silicon layer below said third silicon layer to form first conductive layers between adjacent said third insulating layers; forming a forth insulating layer on said first conductive layers and said third insulating layers; and forming a second conductive layer on said fourth insulating layer is provided.

### BRIEF DESCRIPTION OF THE DRAWINGS

FIG. 1 is a figure showing a manufacturing process of semiconductor devices according to one embodiment of the present invention.

FIG. 2 is a figure showing a manufacturing process of semiconductor devices according to one embodiment of the present invention.

FIG. 3 is an enlarged view of a part shown in “A” in FIG. 2(c).

FIG. 4 is a figure showing a manufacturing process of semiconductor devices according to one embodiment of the present invention.

FIG. 5 is a figure showing manufacturing process of semiconductor devices according to one embodiment of the present invention.

FIG. 6 is a figure showing manufacturing process of semiconductor devices according to one embodiment of the present invention.

FIG. 7 is a cross sectional view of the a semiconductor device in which groove-like open areas, consisting of insulating layers for element isolation and the first silicon layers as basement, having reverse tapers.

FIG. 8 is a cross sectional view of semiconductor devices in which poly-silicon layers are grown selectively only in open areas, and then the poly-silicon layers are formed.

FIG. 9(a) and (b) are graphs showing a comparative result of flatness after performing CMP, in differences of methods for forming poly-silicon layers.

FIG. 10(a) and (b) are figures showing a definition of step height.

FIG. 11(a) and (b) are graphs showing a comparative result of polishing amount of insulating layers in difference of methods for forming poly-silicon layers.

FIG. 12 is a block diagram of a nonvolatile semiconductor memory device according to one embodiment of the present invention.

FIG. 13 is a figure showing a block circuitry diagram of a memory cell array of a nonvolatile semiconductor device shown in FIG. 12

FIG. 14 is a figure showing dependency of layer thickness in flatness characteristic.

### DETAILED DESCRIPTION OF THE INVENTION

The following description of methods for manufacturing semiconductor devices according to one embodiment of the present invention will be explained in detail, with reference to the accompanying drawings. While examples of the method for manufacturing semiconductor devices of the present invention are shown in the embodiments, the methods for manufacturing semiconductor devices according to the present invention will not be limited to these embodiments.

### EMBODIMENT 1

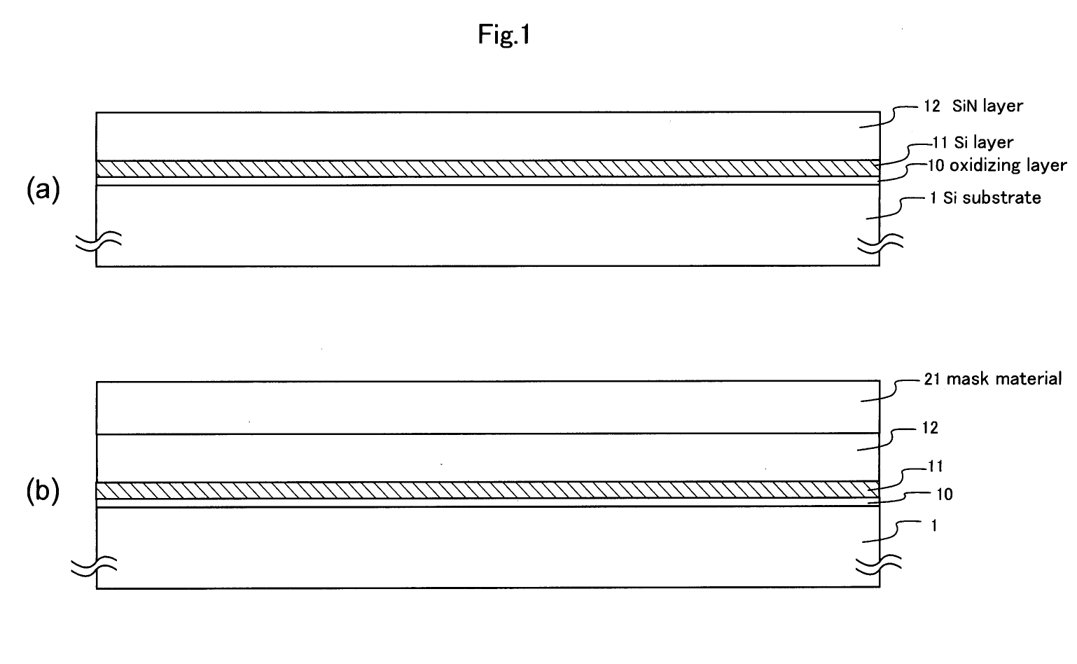

In FIG. 1 to FIG. 6, manufacturing steps of the semiconductor devices according to one exemplary embodiment of the present invention are shown. In the present embodiment, an example of manufacturing nonvolatile semiconductor memory devices will be explained, with reference to FIG. 1 to FIG. 6.

This embodiment provides methods for manufacturing semiconductor devices in which layer formation defects are reduced, variations of device characteristics are reduced, and the yield is improved.

Firstly, as described in FIG. 1(a), after forming thermally-oxidizing layer 10 that will be a tunnel-insulating layer with 9 nm thickness on a silicon substrate 1, a first silicon layer (Si layer) 11 is formed with 40 nm thickness, subsequently, as a stopper layer, for example, a silicon nitride layer (SiN layer) 12 is formed with 150 nm thickness. Phosphorus may be or nor be added in the first silicon layer 11. Also, the first silicon layer 11 may be either amorphous silicon or poly-silicon. If the first silicon layer 11 is an amorphous silicon, roughness of processing edge in the latter steps such as Line Edge Roughness (LER) may be reduced because there is little unevenness of the surface of the first silicon layer 11 and surface of the stopper layer 12 formed on the surface may be planarized. On the other hand, if the first silicon layer 11 is poly-silicon, fine processing in the latter steps is possible because the density is higher compared with amorphous silicon. Moreover, even if the first silicon layer 11 is amorphous silicon, it may be crystallized in heat steps for depositing the SiN layer which is a stopper layer 12 to become poly-silicon. The first silicon layer may be a single crystal silicon layer.

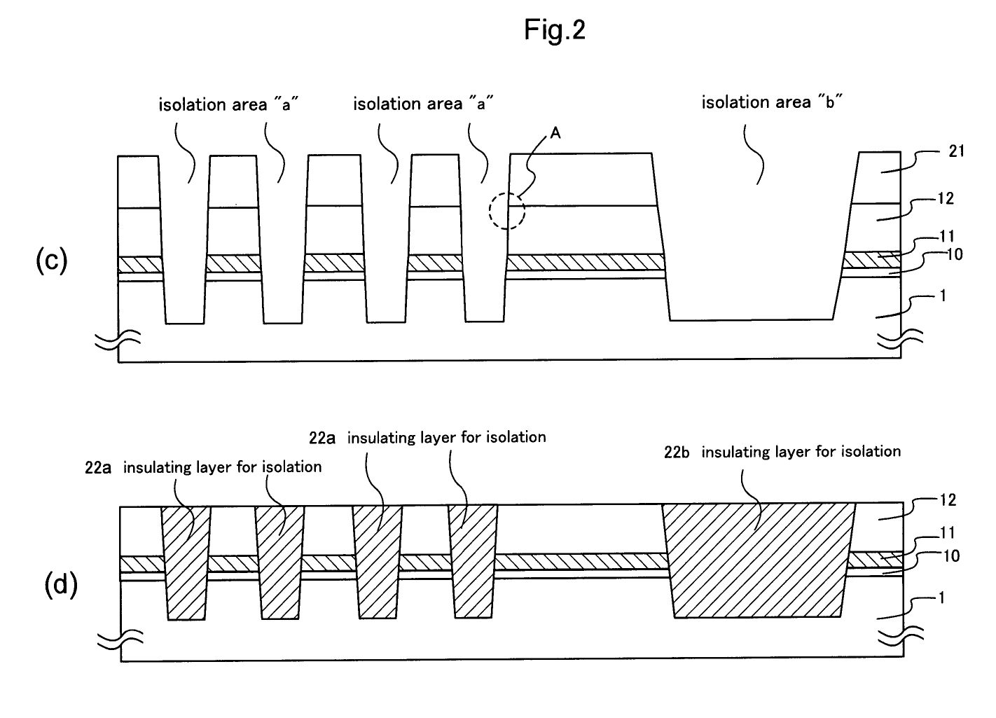

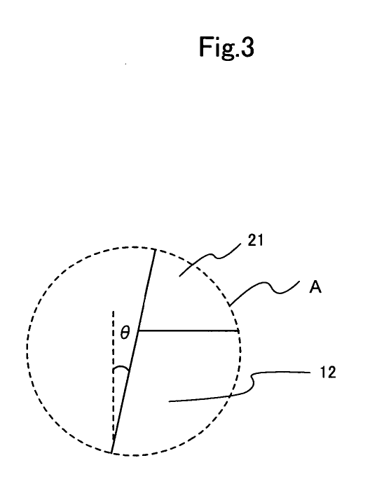

Subsequently, a mask material 21 is deposited as shown in FIG. 1(b). Thereafter, as shown in FIG. 2(c), patterning of the mask materials 21 are performed, and the SiN layer 12 as the stopper layer; the first silicon 11; the tunnel insulating layer 10; and the silicon substrate 1, which are in the area exposed from patterns of mask materials 21, are removed by etching by using Reactive Ion Etching (RIE), and trenches in the parts, which will be element isolation areas “a” and “b”, are formed. The element isolation areas “a” and “b” will become inactive areas, and the other areas which are used for transistors will become active areas. Here in FIG. 2(c), an enlarged view of the parts indicated as “A” is shown in FIG. 3. In the steps shown in FIG. 2(c), forward tapers (θ=0.3° to 5°, typically θ=3°) may be provided in the SiN layer 12, the first silicon layers 11, and the silicon substrate 1 in order to improve embedding characteristics of the insulating layer for element isolation. In this case, the side surfaces of the trenches have forward tapers of 0.3° to 5° to the surface of the silicon substrate 1 respectively.

Subsequently, after removing the mask materials 21, insulating layer is deposited on the SiN layers 12, including the trench parts which will be element isolation areas “a” and “b”. In the present embodiment, the insulating layer has been formed from tetraethoxysilane (TEOS). Additionally, the insulating layer may be formed using High Density Plasma (HDP) CVD.

Next, as shown in FIG. 2(d), the insulating layer is removed out of the trenches by methods such as polishing technique (e.g., CMP) and etch back, etc., using SiN layer 12 as stoppers, then insulating layers 22a and 22b for element isolation are formed. In the present embodiment, CMP has been used. In particular, if CMP is used as a method for using a polishing technique, there is the advantage that variation among cells can be reduced, since the surface following polishing can be made smooth and it can be arranged almost equal to the height of the surface of stopper layers 12 by polishing until the stopper layers 12 are exposed. As this occurs, since the surface of insulating layer for element isolation 22b out of the cells is removed more than required, so-called dishing may occur. The larger area element isolation area “b” has the more significantly dishing occurs. SiN layers will also be removed by 10 nm thickness in the steps shown in the FIG. 2(d).

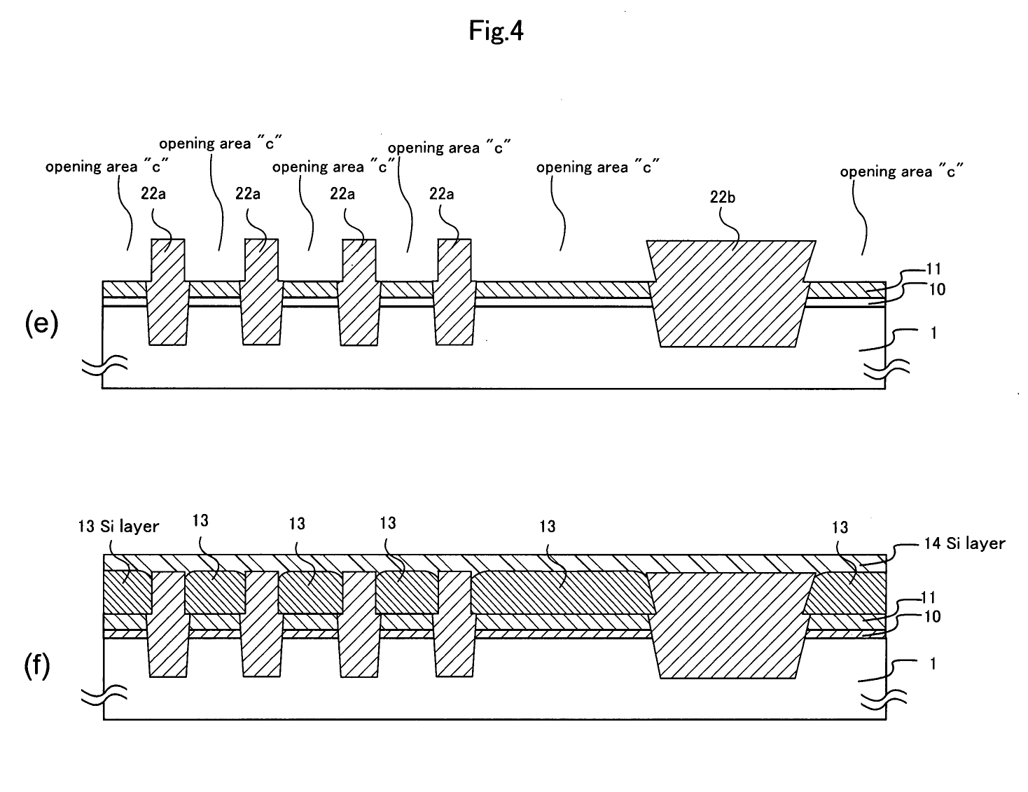

Next, as shown in FIG. 4(e), SiN layers 12 are removed by phosphoric-acid wet etching. If forward tapers (typically θ=3°) are provided in the element isolation areas “a” and “b”, open areas c, which are parts of the SiN layers are removed, are reverse tapers. In addition, depth of the open areas c is 140 nm thickness, the same thickness as that of the SiN layers 12.

Subsequently, etching is performed with diluted hydrofluoric acid (DHF) solution where hydrofluoric acid (HF) diluted with pure water to remove (natural) oxidation layers formed on the surface of the first silicon layers 11. In the present embodiment, the oxidation layers are etched in 5 nm to 10 nm thickness using DHF of 200 times dilution. By the removal process of the oxidation layers, crystals of silicon appear on the surface of the first silicon layers.

Next, as shown in FIG. 4(f), poly-silicon layers 13 are grown selectively by epitaxial growth using the first silicon layers as nuclei. In the present embodiment, at first, the substrate is transported into the forming devices such as LPCVD. After raising the temperature of the inside of a chamber to 850° C., the substrate is baked in hydrogen (H₂) atmosphere under 240-Torr pressure. Afterwards, the temperature of the chamber is lowered to 815° C.; dichlorosilane (DCS), hydrogen chloride (HCl), hydrogen (H₂) and phosphine (PH₃) are supplied as a source gas with a pressure of 52.8 Torr; and the second silicon layers 13 are formed to the desired layer thickness. Further, in the forming of the poly-silicon layers (the second silicon layers) 13, Nitrogen (N₂) may be used instead of hydrogen (H₂), as a carrier gas. By making the second silicon layer 13 grow on the first silicon layer 11 by the selective growth, the insides of the opening areas “c” may be embedded without forming failure such as voids, etc., even if fineness of the memory cells is advanced and the aspect ratio of the open areas c is increased.

After forming of the second silicon layers 13, poly-silicon is consequently grown nonselectively, and in the same layer forming device, a third silicon layers 14 is formed nonselectively as shown in FIG. 4(f). In the present embodiment, after forming the second silicon layer 13, the temperature of the chamber is lowered to 700° C., silane gas is introduced with a pressure of 80 Torr, and a poly-silicon layer (the third silicon layer) 14 is formed nonselectively over the entire substrate with the desired layer thickness.

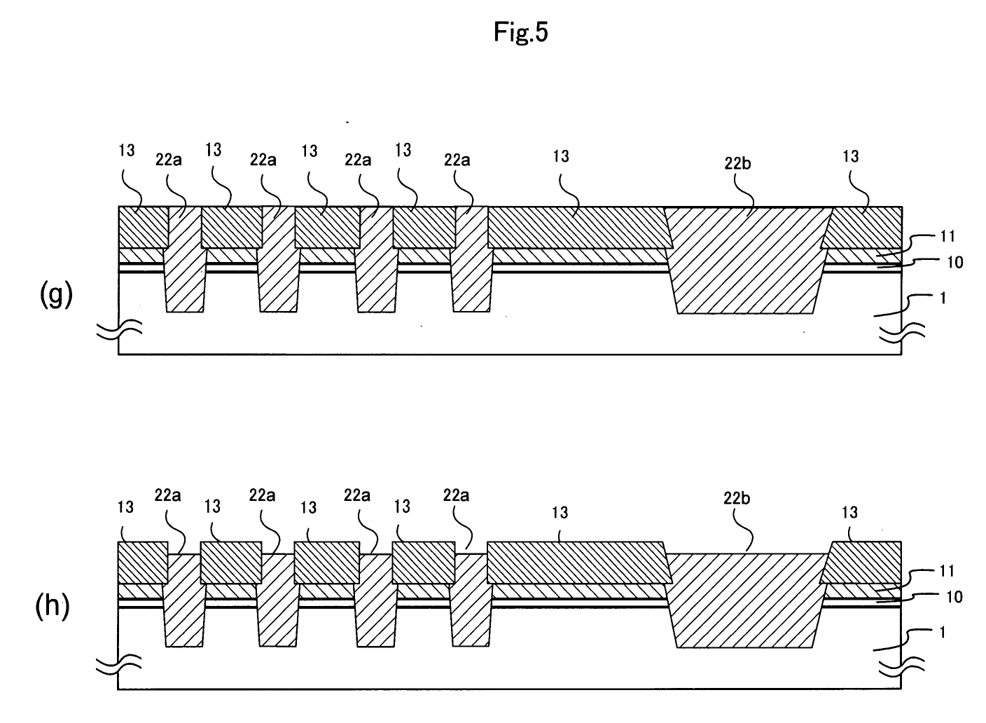

Subsequently, as shown in FIG. 5(g), the surfaces are polished and planarized by CMP. Insulating layers 22a and 22b for element isolation may be prevented from over polishing, since the entire substrate is covered with to-be-polished layers comprising of the nonselectively formed third silicon layer 14. In other words, local occurrence of polishing damages can be prevented in insulating layers 22a and 22b for element isolation; the surface of the second silicon layers 13 are planarized equally and an equal characteristic of electrodes comprising the first silicon layers 11 and the second silicon layers 13 (that will afterwards become floating gates) can be obtained.

In the present embodiment, polished-objective layers are polished using a CMP device (EPO-222 manufactured by Ebara Seisakusho Corporation), and further using a polishing pad made in porous polyurethane (IC1000/Suba400 manufactured by Rodel Inc.), for its slurry using a blended material blended on the polishing pads of colloidal silica; mixture type water disperse system of piperazine (A) and colloidal silica, triethanolamine; water disperse system of hydroxyethyl cellulose (B).

Also, as a polishing condition of the CMP devices, detection of an end point is performed using polishing pressure at 300 g/cm²; wafer RPM at 55 rpm; table RPM at 50 rpm; total slurry flow quantity at 300 ml/min (water disperse system (A) at 50 ml/min; water disperse system (B) at 250 ml/min); polishing time TCM (Table Current Monitor), and polishing is performed under condition of detected end point+25% as over-polishing time setting.

Subsequently, as shown in FIG. 5(h), insulating layers 22a and 22b for element isolation are recessed by about 100 nm by Reactive Ion Etching. Afterwards, only the corners of the second silicon layer 13 may be etched by chemical dry etching to increase the radius of the curvature. In addition, instead of etching the corners, the radius of the curvature may be increased by methods such as oxidation, etc. In the present embodiment, the radius of curvature of the round parts of the corners of the second silicon layers 13 are 500 nm. According to the forms of the second silicon layers 13 in the present embodiment, electric field concentration at the time of device action may be moderated and stability action of the memory cell may be realized.

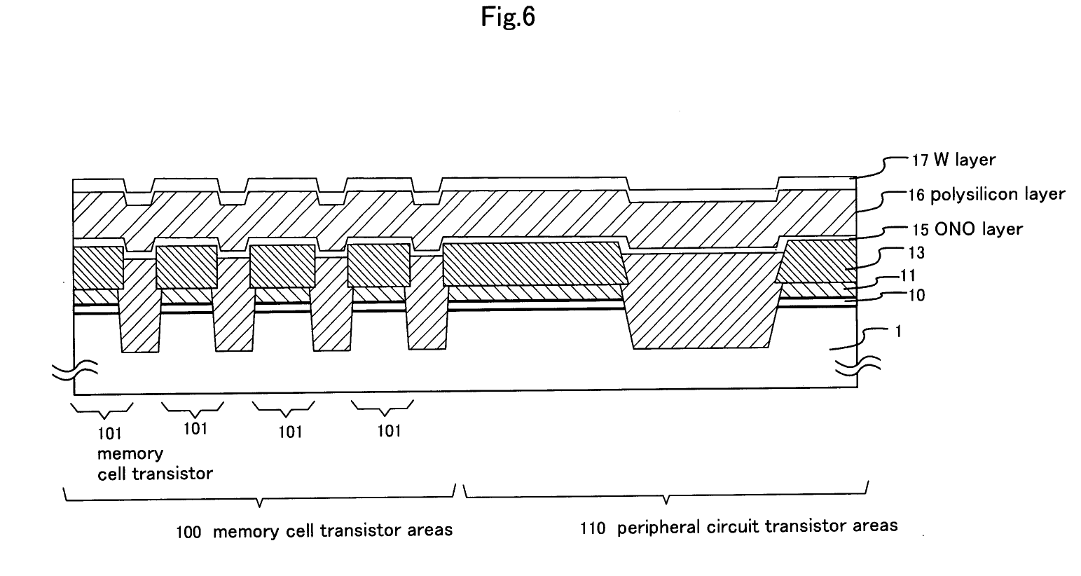

Next, as shown in FIG. 6, an insulating layer 15 among electrodes is formed between floating gates comprising the first silicon layers and the second silicon layers 13 and control gates being formed afterwards. As the insulating layer 15, so-called high-dielectric insulating layer having higher dielectric constant than that of silicon oxide layers, so-called ONO layers comprising silicon oxide layer/silicon nitride layer/silicon oxide layer, or so-called NONON layers comprising silicon nitride layer/silicon oxide layer/silicon nitride layer/silicon oxide layer/silicon nitride layer are used.

Subsequently, poly-silicon layer (P-added Si layer) 16 in which phosphorus is added, are formed at 100 nm thickness, tungsten layer (W layer) 17 is formed at 85 nm thickness in a row. The poly-silicon layer 16 and the tungsten layer 17 become control gates. Further, as occasion demands, short circuits are made between the second silicon layers 13 and poly-silicon layer 16 by setting openings in advance on insulating layers among electrodes outside of the cells.

Next, Reactive Ion Etching patterning silicon layer 16 for control gates and tungsten layer 17 for word line patterns and isolating the floating gates with respect to each memory cell are performed. Impurities are ion-implanted into silicon substrate 1 in self-aligned manner with the obtained patterns so as to form source drain areas (not shown).

With the above-mentioned steps, memory cell transistors 101 are formed in a memory cell transistor area 100, and elements, etc., forming a circuit to control memory cell transistors 101, are formed in peripheral circuits transistor areas 110. After this, by the normal methods, by forming insulating layers inside layer and Bit Lines, etc., a nonvolatile semiconductor memory device is completed.

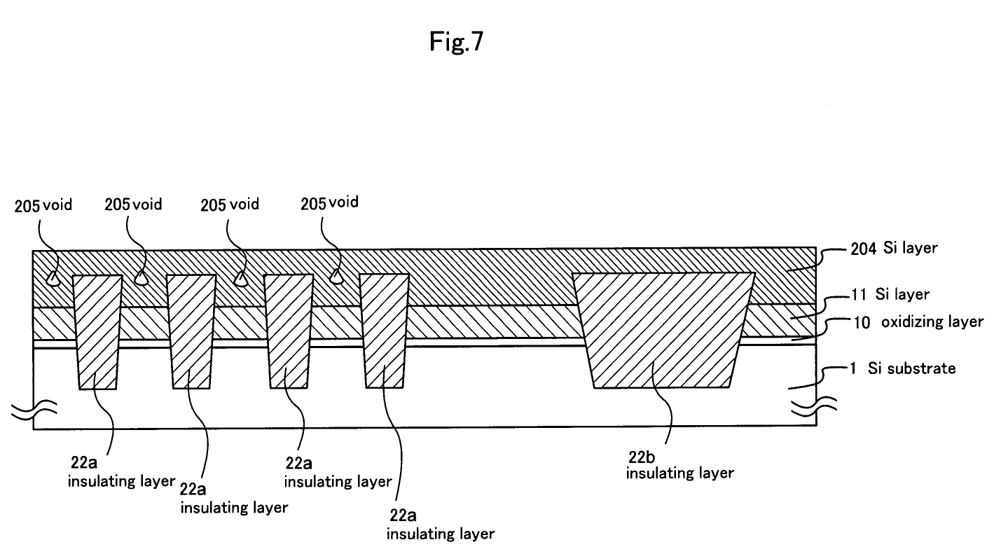

Subsequently, a nonvolatile semiconductor memory device in the prior art and a nonvolatile semiconductor memory device in the present embodiment, that have a difference in their methods of forming silicon layers being floating gates, will be compared and examined. If the poly-silicon layer of the second layer used for floating gates is formed directly on the poly-silicon layer of the first layer and the element isolation area by nonselective growth, there is a problem that cavities can remain in the poly-silicon layers of the second layer used for floating gates with thinness of the memory cells, and thus high-quality memory cells cannot be made. In other words, in the steps of forming poly-silicon layers of the second layer using the damascene process, in particular, if, as shown in FIG. 7, opening-area shapes comprising insulating layers 22a and 22b for element isolation; and the first silicon layers 11 as a base is of reverse-tapered, when poly-silicon (or amorphous silicon) layers 204 are embedded using Low Pressure Chemical Vapor Deposition (hereinafter called LPCVD) method, embedding failure (voids) 205 may occur in the embedded parts. In order to eliminate such cavities in the poly-silicon of the second layer, methods, such as rounding edges of the element isolation areas by etching, or, after depositing the poly-silicon layers of the second layer, primarily etching the poly-silicon of the second layer, then depositing the poly-silicon layers of the third layer, etc., are considered. However, all of the methods are time consuming and can complicate the process. And conventionally, after the deposition of the poly-silicon layer of the second poly-silicon, the poly-silicon layer of the second layer and element isolation areas are arranged at the same height by etching removal of the surface; however, by these steps, there was a problem in which it is difficult to remove poly-silicon layers completely deposited on the element isolation areas whose area is large and the mutual floating gate has short circuit among the adjacent memory cells.

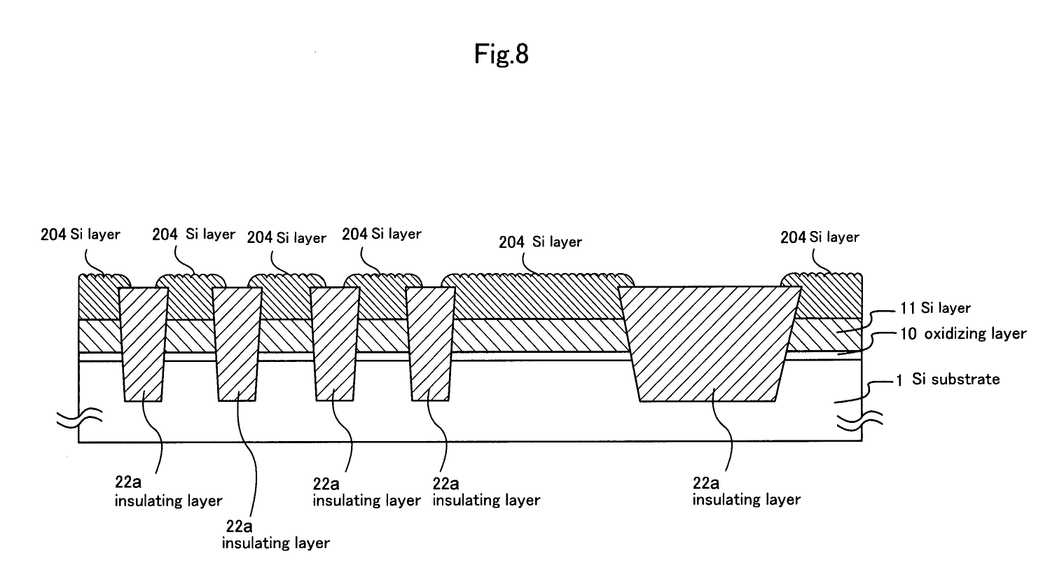

In order to solve these problems, as shown in FIG. 8, there is a Void-Free Method by selective growth of the poly-silicon only the opening areas on the first silicon layers 11 and by forming a poly-silicon layer 204. According to the process shown in FIG. 8, however, the surface of poly-silicon formed by selective growth has inevitably a large amount of unevenness because its material is a poly-crystal, and because variation occurs in the opposite area among the layers of electrodes per individual cell if they remain as they are. Further variation occurs in the coupling ratio per cell. Further in the method, the amount of the coupling ratio and the space of floating gates are in a trade-off relationship, it is becoming more difficult to obtain a larger coupling ratio as the element density is increases, and a limitation to increasing the amount of coupling ratio will occur.

On the other hand, after forming the poly-silicon layer 204 by selective growth, if, for instance, the whole surface is polished and the poly-silicon layer 204 is left only in the opening area, variation restraint of the surface area of the poly-silicon layer 204 among each cell may be expected. In this case, however, the upper parts of insulating layers 22a and 22b for element isolation, where poly-silicon layers 204 are not formed, are over-polished when flatness by Chemical Mechanical Polishing Method is performed (i.e., polishing damages), which consequently becomes one of the factors causing yield deterioration.

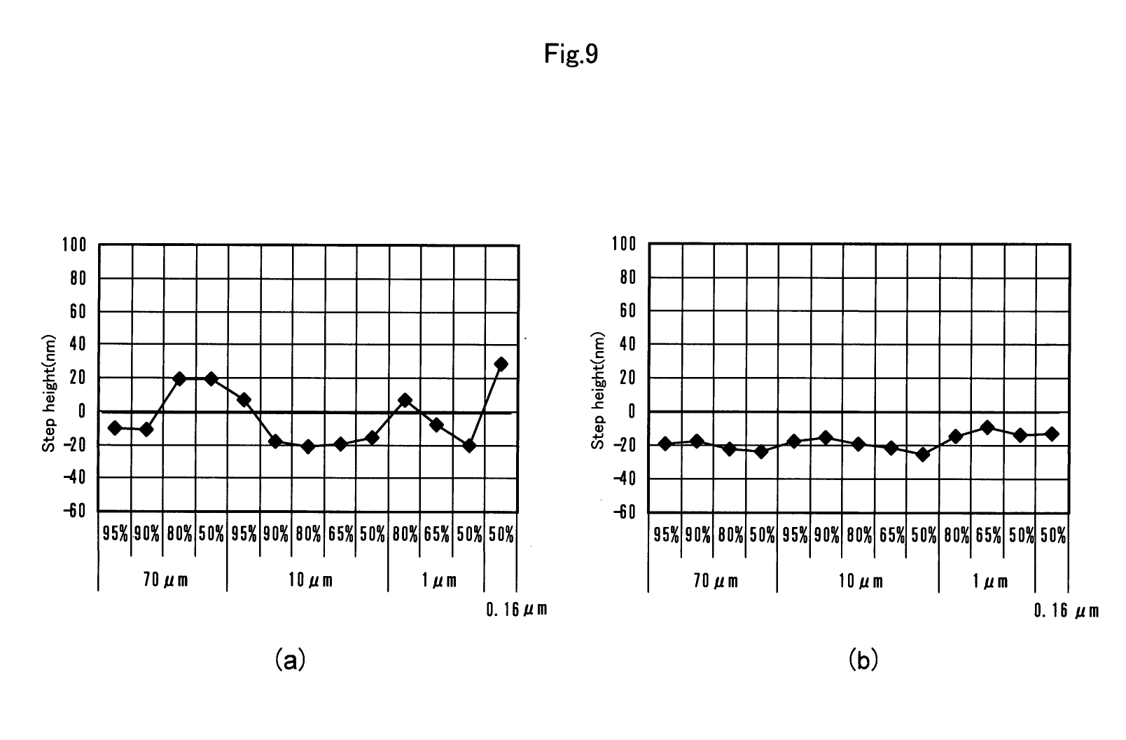

Here, regarding such a process of FIG. 4(f) in a process shown in FIG. 8 and the present embodiment, comparison results of flatness between forming methods after CMP are concretely shown in FIG. 9. That is, FIG. 9(a) is a graph which indicates flatness characteristic in the case of polishing by CMP in a structure where poly-silicon layers 204 formed by selective growth shown in FIG. 8 exist in the surface (hereinafter called “selective-growth structure”, for convenience). On the other hand, for FIG. 9(b) is a graph showing a flatness characteristic in the case of polishing by CMP in a structure shown in FIG. 4(f) produced by the manufacturing method of the present embodiment, i.e., a structure, in which a poly-silicon layer 14 formed by nonselective growth on the poly-silicon layers 13 formed by selective growth is formed on the entire surface of a substrate (hereinafter called “selective and nonselective growth structure”).

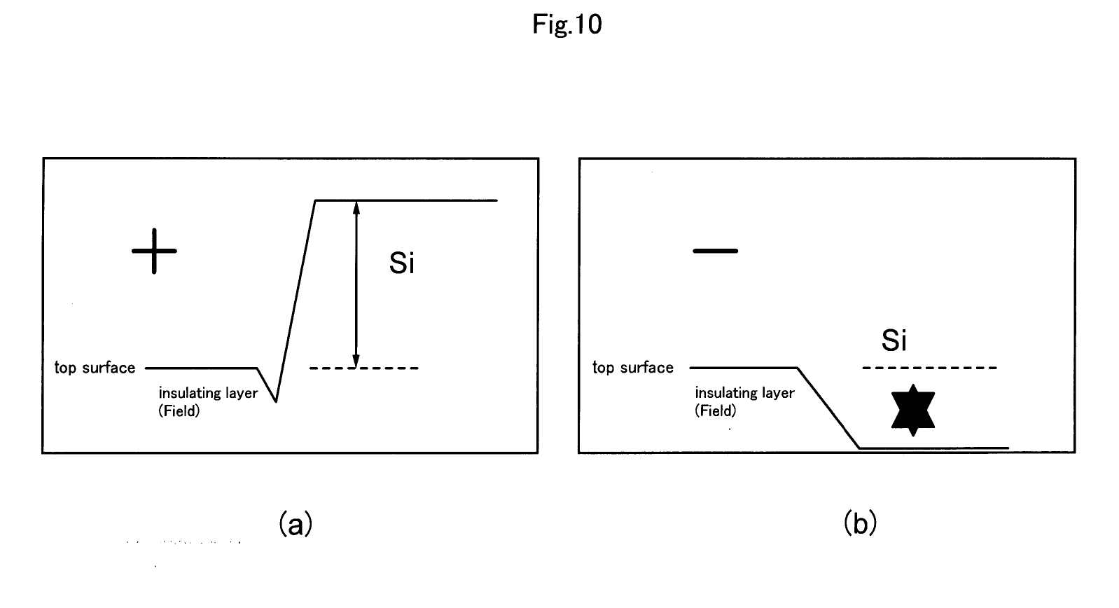

In the graphs of FIG. 9(a) and (b), the cross axis are coating ratios (area of poly-silicon/(area of poly-silicon +area of insulating layers)) in each line width (70 μm, 10 μm, 1 μm, 0.16 μm) after CMP; the vertical axis are step heights showing flatness. A step height is the distance (height) from a reference surface to a surface of poly-silicon layer, as shown in FIG. 10. Step heights are defined as “+” if a surface of poly-silicon layer is beyond the reference surface (FIG. 10 (a)); step heights are defined as “−” if the surface of poly-silicon layer is below the reference surface (FIG. 10(b))

Comparing flatness characteristic of the selective growth structure with flatness characteristic of the selective and nonselective growth structure, flatness characteristic depends on line widths and coating ratios, and variation of an erosion of poly-silicon layer by polishing occurs in the selective-growth structure; in the selective and nonselective growth structure, on the other hand, it be recognized that good flatness may be obtained without any dependence of line widths and coating ratios.

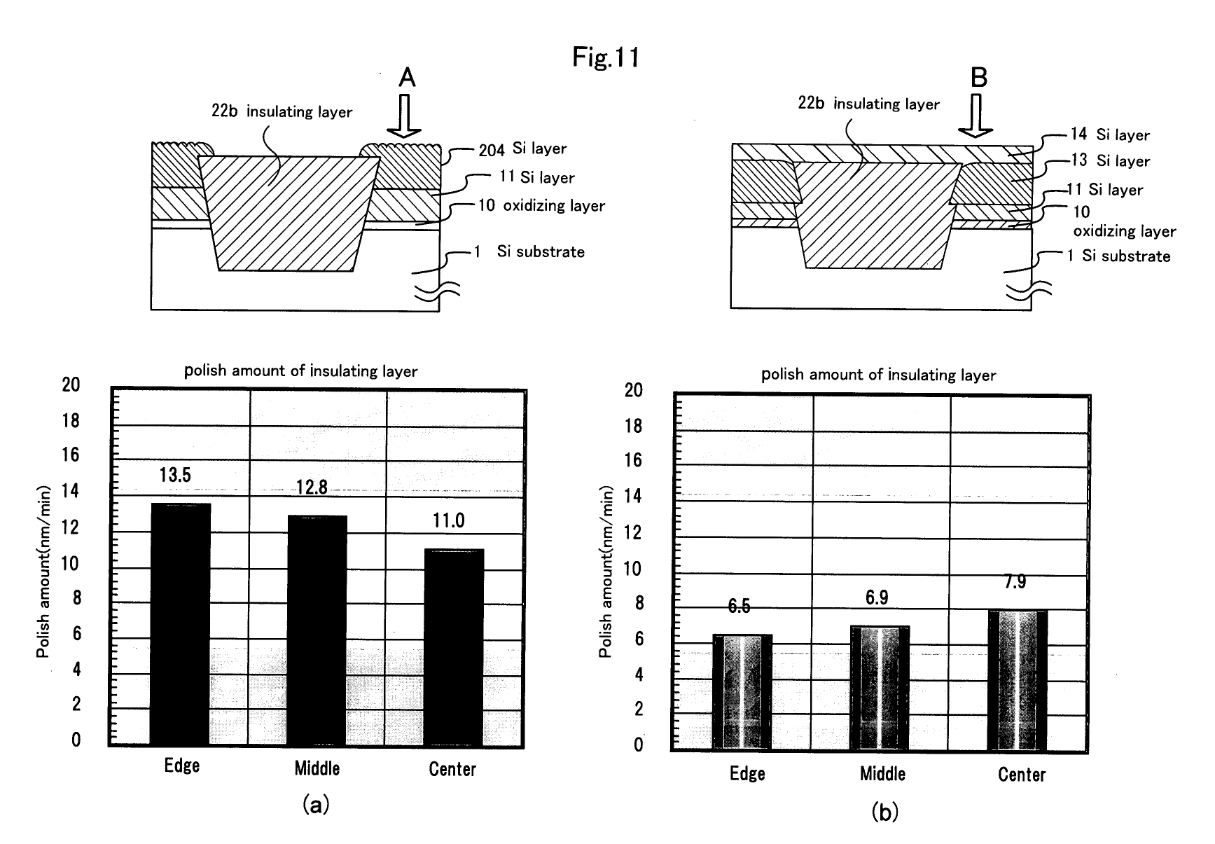

Comparison results for polishing amounts of insulating layers between the forming methods of poly-silicon layers are shown in FIG. 11(a) and (b). FIG. 11(a) shows a graph of measurement results of the polishing amounts of insulating layers in the selective-growth structure; FIG. 11(b) shows a graph of measurement results of the polishing amounts of insulating layers in the selective and nonselective growth structure. In the measurement shown in FIG. 11(a) and (b), three measurement points of the polishing amount of the insulating layers 22b are considered respectively as “Center”, “Middle” and “Edge”, after measuring the parts shown as “A” and “B”. In a condition in which the insulating layers 22b appear on the surface, that is, in a selective-growth structure (FIG. 11(a)), the polishing amounts of Center, Middle and Edge are shown as a large amount, which are 11.0 nm/min, 12.8 nm/min, and 13.5 nm/min, respectively. On the other hand, in a condition in which the insulating layers 22b do not appear on the surface and is covered with a poly-silicon layer 14, that is, in the selective and nonselective growth structure (FIG. 11(b)), the polishing amounts of the insulating layers 22b are largely suppressed, which are 7.9 nm/min, 6.9 nm/min and 6.5 nm/min, respectively.

Therefore, as recognized from the result of the experiment of the polishing amount of insulating layers shown in FIG. 11(a) and (b), according to methods for manufacturing semiconductor devices in the present embodiment, excessive polishing of the insulating layers 22a and 22b may be prevented, since the polishing amount of the insulating layers 22a and 22bare largely suppressed. In turn, while improving forming failure, variations of device characteristic may be reduced and the yield may be improved.

In addition, such as the present embodiment, a uniform characteristic of the floating gates may be obtained by polishing and planarizing surfaces of floating gates of a nonvolatile semiconductor memory device by CMP.

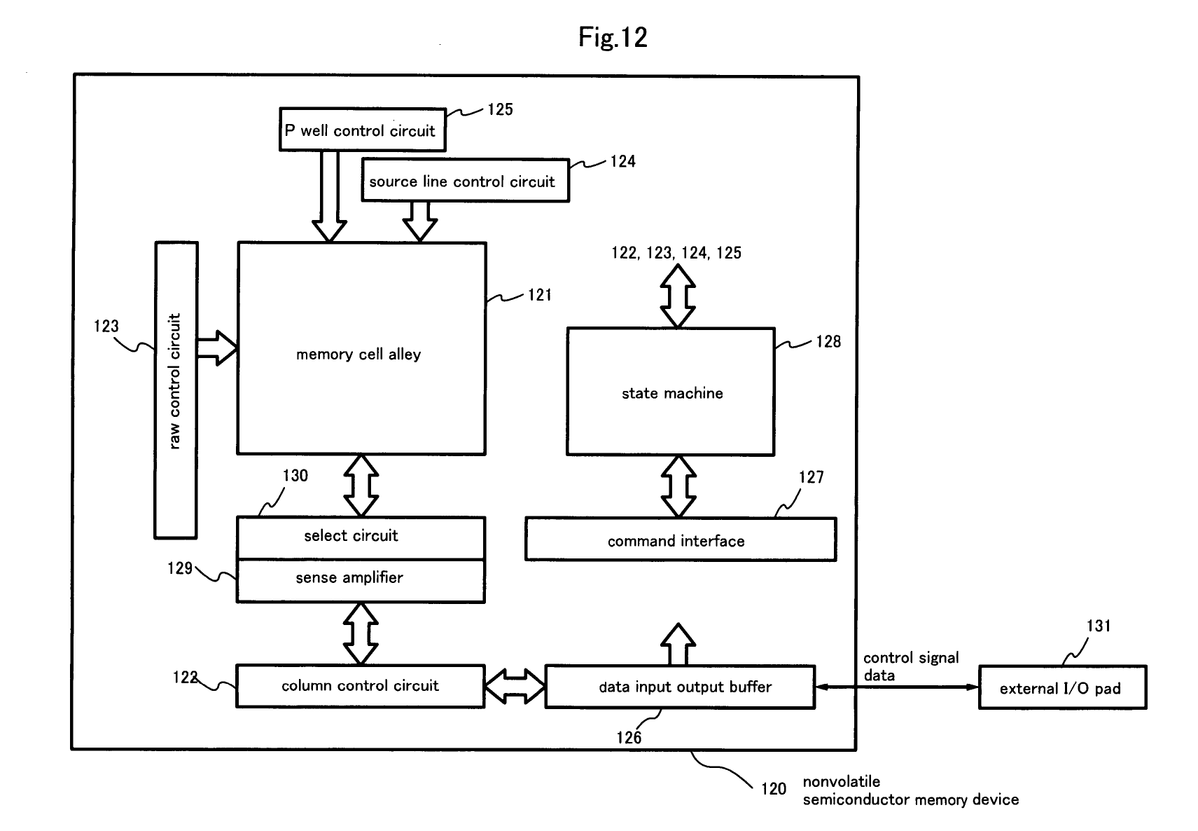

Here, a schematic block diagram of a nonvolatile semiconductor memory device 120 according to the present embodiment is shown in FIG. 12. The nonvolatile semiconductor memory device 120 according to the present embodiment comprises: memory cell array 121; column control circuit (column decoder) 122; a row control circuit (a row decoder) 123, a source line control circuit 124; a P-well control circuit 125; a data input-output buffer 126; a command interface 127; a state machine 128; a sense amplifier 129; and a selection circuit 130. The nonvolatile semiconductor memory device 120 according to the present embodiment performs transmitting and receiving of the data and control signals (commands) with an external I/O pad 131.

In the nonvolatile semiconductor memory device 120 according to the present embodiment, data and control signals are input from the external I/O pad 131 to the command interface 127 and the column control circuit 122, via the data input-output buffer 126. Based on control signals and data, the state machine 128 controls the column control circuit 122, the row control circuit 123, the source line control circuit 124 and the P-well control circuit 125. The state machine 128 outputs an access information for memory cells in the memory cell array 121, to the column control circuit 122 and the row control circuit 123. Based on the access information and data, the column control circuit 122 and the row control circuit 123 control the sense amplifier 129 and the selective circuit 130; activate the memory cells; read out the data; write in the data; or erase the data. The sense amplifier 129 connected to each Bit Lines in the memory cell array 121 loads data to the Bit Lines, further detects electric potential of the Bit Lines and in turn holds in the data cache. Also, the data read out of the memory cells by the sense amplifier 129 which is controlled by the column control circuit 122 output to the external I/O pad 131 via the data input-output buffer 126. The selective circuit 130 performs a selection of the data cache connected to the Bit Lines from a plurality of data caches configuring the sense amplifier.

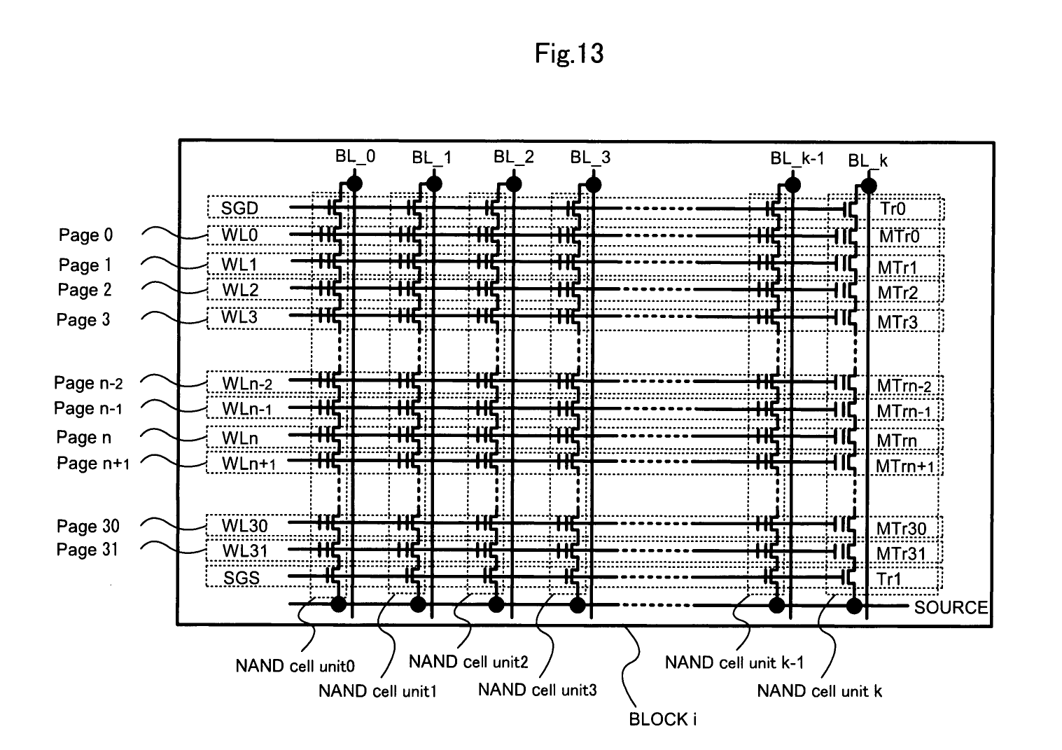

Here, a schematic circuit configuration of the memory cell array 121 is shown in FIG. 13. The memory cell arrays 121 is divided into m blocks (BLOCK 0, BLOCK 1, BLOCK 2, . . . , BLOCK i, . . . , BLOCK m). Here, “a block” refers to a minimum unit of data erasure.

In addition, each of blocks BLOCK 0 to m, such as block BLOCK i typically shown in FIG. 13, is comprised of k NAND cell units 0 to k, respectively. In the present embodiment, each of the NAND cell units comprises 32 memory cells MTr 0 to 31 connecting in series. One edge of the memory cells is connected to Bit Lines (BL) BL_0, BL_1, BL_2, BL_3, . . . , BL_k−1, BL_k through a selection gate transistor Tr 0 connected to a selection gate line (SGD); the other edge of the memory cells is connected to a common source line (SOURCE) through a selection gate transistor Tr 1 connected to a selection gate line (SGS). Control gates of each memory cell MTr are connected to word lines WL (WL 0 to 31). Each of the k memory cells MTr connected to one word line stores 1 bit, of data, and these k memory cells MTr comprise a unit called “a page”.

Additionally in the present embodiment, the number of blocks consisting of a memory cell array is assumed to be “m”, and one block is assumed to include k NAND cell units comprising 32 memory cells MTr. However, the present invention is not limited to the above-mentioned numbers, and consequently the number of blocks, memory cells MTr and the number of NAND cell units may be changed in desired capacity. Further in the present embodiment, it is assumed that each memory cell MTr stores one bit of data; however, it may also be assumed that each memory cell MTr stores plural bits of data (multiple-level bit data) with amount of electron injection. And in the present embodiment, a NAND-type flash memory in which one NAND cell unit is connected to one Bit Line BL is explained, but the invention may also be applied to a NAND-type flash memory of so-called Shared Bit Line type in which a plurality of NAND cell units share one Bit Line.

### EMBODIMENT 2

In the present embodiment, amorphous silicon layers are formed as the silicon layers 11 in the above-mentioned Embodiment 1; the amorphous silicon layers 11 are used as nuclei, poly-silicon layers 13 are grown selectively by epitaxial growth; afterwards, a poly-silicon layer 14 is formed nonselectively by epitaxial growth.

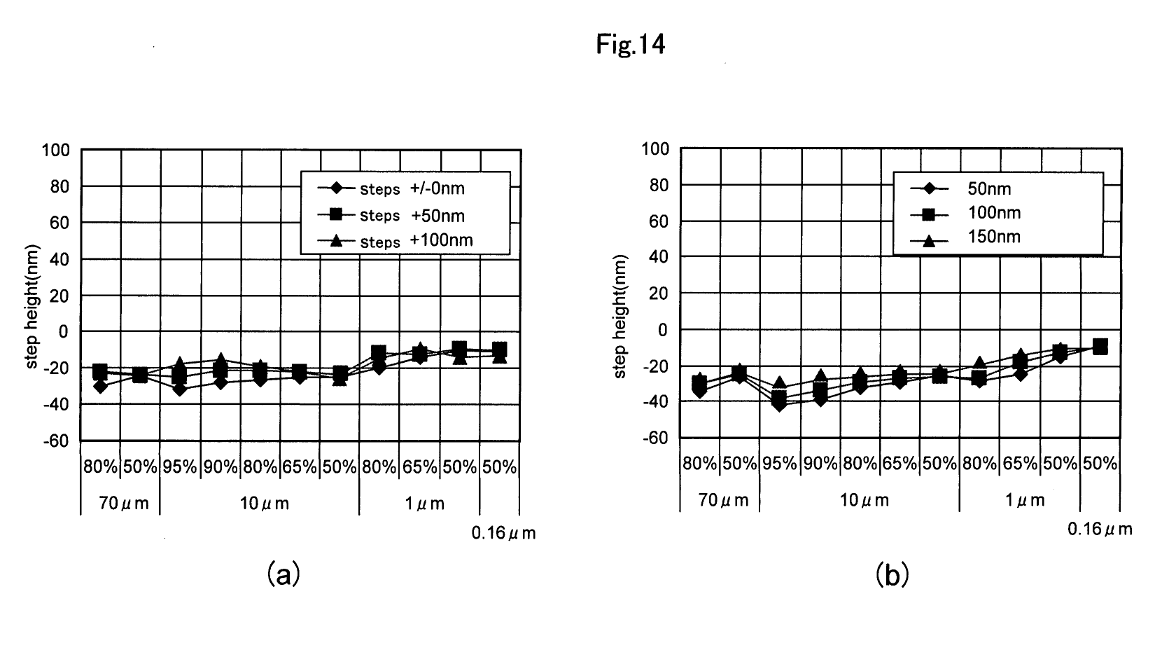

At this time, regarding the flatness characteristic of electrodes of each obtained line widths and each obtained coating ratios, dependency of layer thickness of poly-silicon layers 13 formed by selective growth in the opening areas “c” (See FIG. 4(e)) using the amorphous silicon layers 11 as nuclei, is shown in FIG. 14(a). Further, dependency of layer thickness of a poly-silicon layer 14 formed by nonselective growth on the poly-silicon layers 13 and the insulating layers 22a and 22b for element isolation, is shown in FIG. 14(b).

In the present embodiment, formation of the poly-silicon layers 13 (with the thickness of ±0 nm (□), +50 nm (▪), and +100 nm (▴), respectively) is performed for the steps of the opening areas “c” shown in FIG. 4(e), and then the flatness characteristic for each line width and each coating rate have been extracted as shown in FIG. 14(a). In general, because it is desirable that step height be in the range of +20 to −40 nm, and from the result, it is recognized that sufficient flatness may be obtained if the layer thickness of the poly-silicon layers 13 are in the range of ±0 nm to +100 nm for the steps, i.e., in the range of being greater than or equal to the top surface of the insulating layers 22a and 22b and no more than 100 nm.

Next, a result in the case that layer thickness of the poly-silicon layers 13 deposited on the opening areas “c” formed in the steps of +/−0 nm and formed by changing the condition of layer thickness of the nonselective poly-silicon layer 14 of the upper layer is shown in FIG. 14(b) In general, because step height may be in the range of +20 nm to −40 nm, it is recognized that flatness may be fully obtained if the layer thickness of the nonselective poly-silicon layer 14 of the upper layer is in the range of 50 nm to 150 nm on the surface of the insulating layers 22a and 22b, i.e., in the range of greater than 50 nm but no more than 150 nm from the top surface of the insulating layers 22a and 22b.

### EMBODIMENT 3

In the present embodiment, examples of a dual-liquid mixture type water disperse system and a component-blended type water disperse system having blended and adjusted components used as a slurry of CMP during a step for polishing an object to be polished shown in FIG. 5(g) are explained. Further, each of the components presented as follows are merely examples, and the slurry which may be used for polishing steps is not limited to the following examples.

Component-blended Type Water Disperse System

For a component-blended type water disperse system, a chemical mechanical water disperse system may be used. The chemical mechanical water disperse system may be obtained by combining at least, solution quaternary ammonium salt, basic organic compound except for solution quaternary ammonium salt, inorganic acid salt, solution macromolecule, abrasive and water system medium.

Dual-liquid Mixture Type Water Disperse

For a dual-liquid mixture type water disperse system, a water disperse system for chemical machines may be used. The water disperse system for chemical machines may comprise mixture of the following: water disperse system (I) which is obtained by combining at least solution quaternary ammonium salt, inorganic acid salt, and water system medium and; a water disperse system (II) which is obtained by combining at least solution macromolecule, basic organic compound except for solution quaternary ammonium salt, and water system medium. The water disperse system for chemical machines may further combined abrasive at least in either one of the above-described water disperse system (I) or the above-mentioned water disperse system (II)

Solution Quaternary Ammonium Salt and the Other Basic Organic Compounds

As solution quaternary ammonium salt, quaternary alkyl ammonium salt may be used. For solution quaternary alkyl ammonium salt, a compound represented in the equation described below may be used.
[NR4]+[OH]− (A),
wherein R refers to an alkyl group of carbon number 1 to 4. All of these 4 Rs may be either the same or different respectively. As its specific example, compounds, such as: tetrametylammonium hydroxide; tetraethylammonium hydroxide; tetrapropylammonium hydroxide; tetraisopropylammonium hydroxide; tetrabtylammonium hydroxide; and tetraisobtylammonium hydroxide are exemplified. In these compounds, tetrametylammonium hydroxide and tetraethylammonium hydroxide maybe used. These solution quaternary alkylammonium salts may be used by themselves, and more than one type of these may be blended to use.

Further, as a basic organic compound except for solution quaternary ammonium salts, solution amine is proposed. As solution amines, (a) alkylamine such as methylamine, dimethylamine, trimethylamine, ethyl amine, diethylamine, triethylamine, etc.; (b) alkanolamine such as diethanolamine, triethanolamine, aminoetyl etanolamine, etc.; (c) alkylene amines such as diethylenetriamine, triethylenetetramine, tetraethylenepentamine, pentaethylene hexamine, and triethylene diamine, etc.; (d) perazine types such as piperazine-hexahydrate, piperazine anhydride, aminoethylpiperazine, N-methyl piperazine, etc.; and imine types such as polyethylene imine, etc. are proposed. Among these, diethanolamine, triethanolamine, etc. may be used. The above-mentioned solution amines may be used by themselves, and, more than one type of the solution amines may be blended to use.

Solution Quaternary Ammonium Salt and the Other Basic Organic Compounds-mass

A combination amount of solution quaternary alkyl ammonium salt and basic organic compounds except for solution quaternary alkyl ammonium salt may be respectively 0.005 to 10 mass % for each total amount of component-blended type water disperse system and dual-liquid mixture type water disperse. This may be 0.005 to 8 mass %. This may be 0.008 to 5 mass %. This may be 0.01 to 4 mass %. If the combination amount of the solution quaternary alkyl ammonium salt and the basic organic compounds except for the solution quaternary alkyl ammonium salt is less than 0.005 mass %, polishing velocity may not be sufficiently obtained. On the other hand, it be sufficient if the combination amount of the basic organic compounds is 10 mass %. Yet, the basic organic compounds such as the solution quaternary ammonium salt dissolve in the water disperse system, and at least a part of the basic organic compounds contains ions.

Inorganic Acid Salt

As inorganic acid salt, inorganic acid sodium salt such as hydrochloric acid, nitric acid, sulfuric acid, carbonic acid and phosphoric acid; potassium salt, ammonium salt, sodium salts having sulfuric acid hydrogen ion, carbonic acid hydrogen ion, and phosphoric acid hydrogen ion, potassium salt, ammonium salt, are proposed. Among these ammonium salts may be used, and further carbonic acid ammonium, ammonium nitrate and ammonium sulfate may be used. These inorganic acid salts may be used by themselves, and more than one type of these also may be blended to use.

Inorganic Acid Salt—Mass

The combination amount of the inorganic acid salts may be 0.005 to 8 mass % for each of the total amount of component-blended type water disperse system and dual-liquid mixture type water disperse. This maybe 0.005 to 6 mass %. This may be 0.008 to 4 mass %. This may be 0.01 to 3 mass %. If the combination amount of inorganic acid salt is less than 0.005 mass %, inhibition effects of dishing and erosion could be insufficient. Alternatively, the value of the combination amount will be sufficient at 8 mass %.

Solution Macromolecule

As solution macromolecule, cellulose types such as ethyl cellulose; methyl hydroxy ethyl cellulose; methyl hydroxy propyl cellulose; hydroxy ethyl cellulose; hydroxy propyl cellulose; carboxy-methyl cellulose; and carboxy-methyl hydroxy-ethyl cellulose etc, polyethylene glycol, polyethylene imine, polyvinyl pyrrolidone, polyvinyl alchohol, polyacrylic acid and its salt, and solution macromolecules such as polyacrylic amide; polyethylene oxide; etc, are proposed. Among these, cellulose types and polyacrylic acid and its salt may be used. Hydroxy-ethyl cellulose and carboxy methyl cellulose are may be used. These macromolecules may be used by themselves, andmore than one type of these also may be blended to use.

Solution Macromolecule—Most Favorable Mass

The combination amount of solution macromolecules may be 0.005 to 5 mass % for each of the total amount of the component-blended type water disperse system and dual-liquid mixture type water disperse. This may be 0.005 to 3 mass %. This may be 0.008 to 2 mass %. This may be 0.01 to 1 mass %. If the combination amount of the solution macromolecule is less than 0.005 mass %, inhibition effects of dishing and erosion could be insufficient, and surface defect of wafers could be increased. Alternatively, the value of the combination amount will be sufficient at 5 mass %.

Abrasive

As abrasive, inorganic particles, organic particles and organic-inorganic composition particles are proposed. The above-mentioned inorganic particles, silicon dioxide, aluminumoxide, ceriumoxide, titaniumoxide, zirconia, silicon nitride, and manganese dioxide, etc., are proposed. Among these, silicon dioxide may be used. As such silicon dioxide, to be concrete, fumed silica, synthesized by a fumed method in which silicon chloride etc., reacts with oxygen or hydrogen in a vapor phase, colloidal silica synthesized by a gel-sol method in which metal alkoxide is hydrolyzed and condensed, colloidal silica synthesized by an inorganic colloidal method in which impurities are removed by refinement, etc., are proposed.

As an organic particle, particles consisting of: (1) polystyrene and styrene system copolymerization element; (2) acrylic acid resin such as polymethyl methacrylate and acrylic system copolymerization element; (3) polyvinyl chloride, polyamide, polyimide, polycarbonate, phenoxy resin and; (4) copolymerization element such as polyethylene and polypropylene, etc., maybe used. Among these, (1) polystyrene and styrene system copolymerization element and (2) acrylic acid resin such as polymethyl methacrylate and acrylic system copolymerization element may be used.

Abrasive Particles Diameter

Examples of a diameter of particle used for a component-blended type water disperse system and dual-liquid mixture type water disperse will be explained. Particles are considered to exist often in the state that primary particles are associating or condensing (secondary particles) in the component-blended type water disperse system and dual-liquid mixture type water disperse, if the particles are those with a relatively small diameter, for example, colloidal silica synthesized by the gel-sol method and the colloid method, etc. The average diameters of the primary particles at that time may be 1 to 3000 nm. The average diameters may be 2 to 1000 nm. Moreover, the average diameters of the secondary particles at that time may be 5 to 5000 nm. The average diameters may be 5 to 3000 nm. The average diameters may be 10 to 1000 nm. If the average diameters of the secondary particles are less than 5 nm, polishing velocity may not be sufficiently obtained. On the other hand, if the value is more than 5000 nm, inhibition effects of dishing and erosion could be insufficient. In addition, scratches etc. could occur on the wafer surface and this may cause an increase of surface defect.

Meanwhile, because particles such as silica, etc. which are synthesized by the Hume method, are originally manufactured in a form of the secondary particles, and thus because it is very difficult to disperse the (already second) particles in a form of primary particles in the component-blended type water disperse system and dual-liquid mixture type water disperse, it is considered that the primary particles are coagulated as secondary particles, as in the above explanation. Therefore, particles such as silica synthesized by the fumed method may be sufficient only with regulating the diameter of the secondary particles. The average diameters of secondary particles of particles such as silica synthesized by the fumed method may be 10 to 10000 nm. The average diameters may be 20 to 7000 nm. The average diameters may be 50 to 5000 nm. By making the average diameters of the secondary particles in the above-described ranges, high polishing velocity, and inhibition effect of dishing and erosion may be obtained.

Organic particles are considered to exist mostly as a single particle in the component-blended type water disperse system and dual-liquid mixture type water disperses. The average diameters of the inorganic particles may be 10 to 5000 nm. The average diameters may be 15 to 3000 nm. The average diameters maybe 20 to 1000 nm. By making the average diameters of the particles in the above-described ranges, high polishing velocity, and inhibition effect of dishing and erosion may be obtained.

pH

Example of pH of the mixture type water disperse system is 9 to 13 nm. The pH of the mixture type water disperse system may be 9 to 12. If the pH is less than 8, sufficient polishing performance could not be obtained; if the pH is more than 13, it is not preferred because a stability of the mixture type water disperse system may be deteriorated. The pH of the entire mixture type water disperse system after the mixture in the case that the two liquids are mixed to use, may be in the range as in the above-described values, and thus each pH of the mixture type water disperse system is not limited to this embodiment.

What is claimed is:

1. A method for manufacturing a semiconductor device comprising:
forming a first silicon layer above a semiconductor substrate;
forming a stopper layer on said first silicon layer;
partially removing said stopper layer and said first silicon layer above said semiconductor substrate to form a plurality of trenches;
forming an insulating layer on said stopper layer with inside of said trenches;
partially removing said insulating layer to expose said stopper layer;
after partially removing said insulating layer, removing said stopper layer to expose said first silicon layer;
selectively growing second silicon layer on said exposed first silicon layer;
nonselectively growing a third silicon layer on said second silicon layer; and
polishing at least a surface of said third silicon layer by performing chemical mechanical polishing.

2. The method for manufacturing a semiconductor device according to claim 1 wherein polishing said third silicon layer is performed so as to expose said insulating layer below said third silicon layer.

3. The method for manufacturing a semiconductor device according to claim 1 wherein said first, second and third silicon layers are poly-silicon layers.

4. The method for manufacturing a semiconductor device according to claim 1 wherein said first silicon layer is amorphous silicon, and said second and third silicon layers are poly-silicon layers.

5. The method for manufacturing a semiconductor device according to claim 1 wherein said second silicon layer is grown until a height of said second silicon layer being greater than or equal to the top surface of said insulating layer but no more than 100 nm.

6. The method for manufacturing a semiconductor device according to claim 1 wherein said third silicon layer is grown until a height of said third silicon layer being greater than 50 nm but no more than 150 nm from the top surface of said insulating layer.

7. The method for manufacturing a semiconductor device according to claim 1 wherein the side surfaces of said trenches have forward tapers of 0.3° to 5° to the surface of said semiconductor substrate respectively.

8. The method for manufacturing a semiconductor device according to claim 1, further comprising forming another insulating layer on said polished surface.

9. The method for manufacturing a semiconductor device according to claim 8 wherein said another insulating layer comprises silicon oxide layer/silicon nitride layer/silicon oxide layer, or silicon nitride layer/silicon oxide layer/silicon nitride layer/silicon oxide layer/silicon nitride layer.

10. The method for manufacturing a semiconductor device according to claim 1 wherein said semiconductor device is a nonvolatile semiconductor memory device.

11. A method for manufacturing a semiconductor device comprising:
forming a first insulating layer on a semiconductor substrate;
forming a first silicon layer on said first insulating layer;
forming a second insulating layer on said first silicon layer;
partially removing said second insulating layer, said first silicon layer, said first insulating layer and said semiconductor substrate to form a plurality of trenches for isolation;
filling said trenches for isolation with third insulating layers;
after filling said trenches with third insulating layers, removing said second insulating layer to expose said first silicon layer;
selectively growing a second silicon layer on said exposed first silicon layer;
nonselectively growing a third silicon layer on said second silicon layer and said third insulating layers;
planarizing said third silicon layer and said second silicon layer below said third silicon layer to form first conductive layers between adjacent said third insulating layers;
forming a forth insulating layer on said first conductive layers and said third insulating layers; and
forming a second conductive layer on said fourth insulating layer.

12. The method for manufacturing a semiconductor device according to claim 11 wherein said planarizing said third silicon layer and said second silicon layer is performed by chemical mechanical polishing (CMP).

13. The method for manufacturing a semiconductor device according to claim 11 wherein said first, second and third silicon layers are poly-silicon layers.

14. The method for manufacturing a semiconductor device according to claim 11 wherein said first silicon layer is amorphous silicon, and said second and third silicon layers are poly-silicon layers.

15. The method for manufacturing a semiconductor device according to claim 11 further comprising, partially removing said third insulating layers after planarizing said third silicon layer and said second silicon layer.

16. The method for manufacturing a semiconductor device according to claim 11 wherein said second silicon layer is grown until a height of said second silicon layer being greater than or equal to the top surfaces of said third insulating layers but no more than 100 nm.

17. The method for manufacturing a semiconductor device according to claim 11 wherein said third silicon layer is grown until a height of said third silicon layer being greater than 50 nm but no more than 150 nm from the top surfaces of said third insulating layers.

18. The method for manufacturing a semiconductor device according to claim 11 wherein the side surfaces of said trenches have forward tapers of 0.3° to 5° to the surface of said semiconductor substrate respectively.

19. The method for manufacturing a semiconductor device according to claim 11 wherein said fourth insulating layer comprises silicon oxide layer/silicon nitride layer/silicon oxide layer, or silicon nitride layer/silicon oxide layer/silicon nitride layer/silicon oxide layer/silicon nitride layer.

20. The method for manufacturing a semiconductor device according to claim 11 wherein said semiconductor device is a nonvolatile semiconductor memory device.
